(19) United States
(12) Patent Application Publication
(10) Pub. No.: US 2007/0228392 A1
(43) Pub. Date: Oct. 4, 2007

(54) Semiconductor radiation source and light curing device

(75) Inventors: Wolfgang Plank, Rankweil (AT); Bruno Senn, Buchs (CH)

Correspondence Address: John C. Thompson, 69 Grayton Road, Tonawanda, NY, 14150, US

(73) Assignee: Ivoclar Vivadent AG

(21) Appl. No.: 11/728,239

(22) Filed: Mar. 23, 2007

(30) Foreign Application Priority Data
Apr. 3, 2006 (DE) 10 2006 015 377.4

(51) Int. Cl. H01L 33/00

(52) U.S. Cl. 257/79

(57) ABSTRACT

A semiconductor radiation source has a base body on which at least two LED chips are directly mounted and are fitted to the base body using a thermally conductive connection. At least one printed circuit board is mounted on the base body and extends from the centrally arranged LED chips to the outside, in particular to the peripheral region of the base body, and projects, in particular, into free areas which extend laterally beside the chips or between the latter.

### CROSS-REFERENCE TO RELATED APPLICATIONS

This application claims foreign priority benefits under 35 U.S.C. §119 from German patent application Ser. No. 10 2006 015 377.4 filed Apr. 3, 2006.

### TECHNICAL FIELD

The invention relates to a semiconductor radiation source having a base body, at least two centrally arranged LED chips directly mounted to the base body using a thermally conductive connection, and at least one printed circuit board mounted on the base body and which extends from the centrally arranged LED chips to the outside, in particular to the peripheral region of the base body.

### BACKGROUND OF THE INVENTION

In the case of a semiconductor radiation source of this type, it has already been proposed to centrally mount at least two LED chips on a heat sink and to focus the light emitted by the LED chips using a common converging lens. The light emission is particularly efficient if the LED chips are arranged such that they are closely adjacent to the focal point of the lens. In addition to the high optical power, a closely adjacent arrangement of this type generates considerable thermal power there. In this respect, it has been known for a long time to use heat sinks to dissipate the thermal power. It is decisive for the luminous efficiency that effective cooling is carried out in this case in order to avoid exceeding the operating temperature range of the LED chips.

High-power LED chips, in particular, must be stored in a sealed manner for reliable operation. In order to achieve this, it has been known for a long time to pot the LED chips in plastic bodies. However, this necessitates a prescribed shape of a lens body. In many cases, it would be desirable to use a material having a higher index of refraction instead of the conventional potting compound, with the result that a separate lens is desirable. By way of example, a lens of this type may be composed of a plastic having a high index of refraction or glass. However, since it is an optical precision component, this lens should not, on the other hand, be subjected to excessive thermal fluctuations so that it is not deformed or does not become opaque.

In order to ensure good heat dissipation, it has become known to fill the space between the lens and the chip, using a liquid. This enables considerably improved heat dissipation in comparison with a filling of air. The background to this is that, as a result of convection, the liquid flows between the comparatively cool surface of the heat sink and the LED chips, with the result that heat is exchanged.

However, in the case of a liquid filling, it must be ensured that the space between the lens and the chip is reliably sealed. This seal is comparatively complex since it must typically also be taken into account that the liquid expands on account of heating. The resultant problems are greater the greater the heat loss generated by the LED chips, while, on the other hand, high-power chips, in particular, emit a very large amount of thermal radiation.

In order to be able to dissipate the heat in an improved manner, it has already been proposed to fit a multiplicity of LED chips in a distributed manner. Although this also makes it possible to provide a very high overall optical power, it is a considerably more complicated matter to focus the light beam, especially when introduced into a light guide, and it is also necessary to mount a multiplicity of individual LED chips, each with the corresponding requirements. The probability of an individual chip failing, that is to say the probability of one of the chips failing, is considerably higher and the design becomes considerably heavier overall which is undesirable in hand-held devices, in particular.

In hand-held devices, in particular, the available space for providing the LED chips is extremely limited. On the other hand, it would be desirable to provide sufficient space for the connections and, if appropriate, also for series resistors for adjusting and calibrating the LED chips but good heat dissipation via the base body and heat shielding toward the front should nevertheless be ensured.

### OBJECTS AND SUMMARY OF THE INVENTION

Therefore, the invention is based on the object of providing a semiconductor radiation source wherein the radiation source is improved as regards the ratio between the light efficiency and the dissipation of power losses without the risk of components which are arranged in front of the semiconductor radiation source being heated to a great extent.

According to the invention, this object is achieved by means providing a base body (22), at least two centrally arranged LED chips directly mounted to the base body using a thermally conductive connection, and at least one printed circuit board (46) mounted on the base body and which extends from the centrally arranged LED chips to the outside, in particular to the peripheral region of the base body (22).

According to the invention, it is particularly favorable if the LED chips are arranged in a central region of the base body in such a manner that they are densely packed, that is to say are adjacent to one another, if appropriate with the interposition of very compact reflector elements. This is to be understood as meaning a central region of the base body which extends, for example, over approximately the central third or less, for example even over the central fifth, of the base body. This allows, first of all, sufficient space to be left for conductor tracks for providing stable and temperature-resistant mechanical connections and, if appropriate, for series resistors. In addition, this central arrangement makes it possible to provide virtually the entire region, for example 90% of the area, of the base body with a printed circuit board. In this case, the printed circuit board has the dual function of routing the connecting lines as close as possible to the LED chips in order to provide suitable connecting areas, in particular for bonding connections. In addition, said printed circuit board is used for heat insulation and thus protects the thermally sensitive optics from radiation from the comparatively hot base body which can thus be used in a particularly efficient manner to dissipate the heat from the LED chips. In this respect, the printed circuit board acts like a type of sheath and covers virtually the entire area of the base body, apart from the area occupied by the LED chips and, if appropriate, by the very small reflector elements.

The reflector elements may be so small that each reflector element occupies, for example, only one tenth of the area of each LED chip, the LED chips being very small anyway. This surprisingly enables particularly good protection of the lens and other sensitive optical components, to be precise also surprisingly from chips which are of distributed design and in which, in this respect, a plurality of punctiform heat sources radiate in a distributed manner.

The finger-like partial coverage of a region, which is radially occupied by LED chips, which is provided in a particularly favorable refinement of the inventive semiconductor radiation source has surprisingly been found to be particularly effective. This makes it possible, on the one hand, to bring the connecting areas for bonding particularly close to the chips but, on the other hand, also results in particularly good heat insulation in very hot regions of the base body.

Arranging the LED chips in the form of a cross or star supports this preferred refinement in which the lateral free areas, that is to say the areas which, when viewed from the side, extend beside an external LED chip, are then completely or at least essentially completely covered by the printed circuit board. Arranging the chips in the form of a cross is preferred in the case of square LED chips, so that, overall, four lateral free areas respectively extend between the limbs of the cross but a star-shaped arrangement, for example a star having three, five or six limbs, also allows the provision of lateral free areas which are then covered by a printed circuit board.

This refinement does not stand in the way of the compact arrangement with good ability to focus the emitted light radiation using a single lens. In this connection, it is particularly favorable if the lens is supported via a spacer which, for its part, is mounted on the printed circuit board, so that even the spacer itself is at a lower temperature level.

In this connection, it is particularly favorable if the LED chips adjoin one another so closely that the width between them is less than one fifth, in particular approximately one tenth, of the diameter of each LED chip.

According to the invention, it is also particularly favorable if, as a result of a reflector element which closely adjoins an individual chip and whose height can be restricted to the height of the LED chip, the radiation maximum emerging there can be used and can be reflected toward the front. This also allows a distance between a parabolic reflector which extends in front of the LED chips or reflector cone in the direction of the optical axis and, in this respect, also allows the introduction of the thermal radiation into the optical reflector to also be reduced without losing emission radiation. In this connection, it is preferred if the emitted light radiation first of all passes through the joint cover lens which is arranged in front of the LED chips and can only then fall onto the parabolic reflector. This allows most of the emitted light radiation to already be focused in advance, so that any soiling of the reflector would also have a less pronounced effect.

A refinement which is particularly favorable according to the invention provides for a spacer which is provided for the lens in front of the LED chips to be of essentially annular shape, the conductor tracks of the printed circuit board extending under the spacer. On the one hand, this enables simple bonding, the bonding wires being effectively protected after the spacer and the lens have been fitted but, on the other hand, enables simple contact-connection to the outside.

The inventive printed circuit board may be composed of any desired suitable heat-insulating material, for example epoxy resin, or else of another plastic which is suitable for this purpose or else of ceramic.

According to another advantageous refinement, provision is made for the printed circuit board to project into free areas which extend laterally beside the chips.

Another advantageous refinement provides for the printed circuit board to run beside the chips but not between the chips and the optical axis of the radiation source.

Another advantageous refinement provides for a first LED chip to be arranged on an optical axis and for a plurality of several LED chips to be radially arranged outside the first LED chip, in particular in such a manner that they are symmetrical with respect to one another and surround the LED chip in the manner of a cross or star.

Another advantageous refinement provides for four further LED chips to surround the first LED chip.

Another advantageous refinement provides for the LED chips to be arranged in the central region of the base body such that they are adjacent to one another, that is to say without the printed circuit board between them.

Another advantageous refinement provides for the printed circuit board to surround the LED chips.

Another advantageous refinement provides for the LED chips and the printed circuit board to essentially have the same height.

Another advantageous refinement provides for connecting areas of conductor tracks of the printed circuit board to be connected to the LED chips via bonding connections, in particular.

Another advantageous refinement provides for the LED chips to be directly mounted on the base body, if appropriate using a thermally conductive adhesive, and for the printed circuit board to be, in particular, adhesively bonded to the base body.

Another advantageous refinement provides for the printed circuit board to have an epoxy resin base, to have at least one conductor track at least on one side, to be coated with copper, in particular, and to be connected by through-plating.

Another advantageous refinement provides for the LED chips to be arranged on a central projection of the base body, the height of said projection essentially corresponding to the height of the printed circuit board.

Another advantageous refinement provides for a reflector element which is supported on the base body and/or the printed circuit board and/or the LED chips, in particular also on the base body, to be arranged at least between two mutually adjacent LED chips.

Another advantageous refinement provides for a reflector element which extends between two LED chips to have two reflecting areas which run essentially obliquely, each reflecting area reflecting radiation emanating from the adjacent LED chip.

Another advantageous refinement provides for the reflecting areas, when viewed in the direction of the optical axis, to essentially extend in a manner corresponding to the height of the printed circuit board or to project beyond the printed circuit board.

Another advantageous refinement provides for reflecting areas to be of slightly concave or parabolic shape, and for the reflector element to have an essentially triangular cross section, in particular essentially that of an isosceles triangle.

Another advantageous refinement provides for a plurality of reflector elements to be connected to one another so as to form a grating reflector.

Another advantageous refinement provides for the LED chips to be held in the grating reflector, and for the grating reflector to be supported on the base body and/or the printed circuit board and/or the LED chips.

Another advantageous refinement provides for reflector elements to extend between the lateral free areas and the LED chips and to support the LED chips, in particular, there.

Another advantageous refinement provides for radiation absorbers which are connected, in particular, to the base body using thermally conductive connections to extend between LED chips, in particular external LED chips, and the printed circuit board.

Another advantageous refinement provides for the radiation absorbers to be simultaneously of heat-insulating design and to be composed of ceramic, in particular.

Another advantageous refinement provides for the radiation absorbers to extend at least over the width of the LED chips and, in particular, to have a greater height than the LED chips, preferably approximately 1.5 to 5 times the height, and particularly preferably approximately twice the height, of the LED chips.

Another advantageous refinement provides for a cover lens to be arranged in the beam path downstream of the LED chips and for a spacer for said lens to be of essentially tubular or annular design, and for the spacer to be at least partially supported on the printed circuit board and/or the base body.

Another advantageous refinement provides for at least one conductor track of the printed circuit board to run through under a spacer and, in particular, to run from outside the spacer to inside the spacer.

Another advantageous refinement provides for a closed space which has a transparent or translucent, liquid or gelatinous substance, in particular silicone gel or a potting compound, to extend between the LED chips, the spacer and the cover lens.

Another advantageous refinement provides for the substance to have phosphorus particles.

Another advantageous refinement provides for a converging lens whose diameter is, in particular, larger than the diameter of a cover lens to be arranged in the beam path downstream of the cover lens. reflector to be arranged at a distance from the LED chips in front of the latter, that is to say downstream of the latter in the beam path, and/or to also be arranged, in particular, downstream of a cover lens in the beam path.

Another advantageous refinement provides for a light guide to be arranged in the beam path downstream of the reflector.

Another advantageous refinement provides for series resistors which can be adjusted, in particular, and are freely accessible for adjustment to be arranged on the printed circuit board outside the spacer.

Another advantageous refinement provides for the first LED chip and the further LED chips to emit light at different wavelengths, in particular at 400 to 430 nm, on the one hand, and at 450 to 480 nm, on the other hand.

Another advantageous refinement provides for the first chip and the further chips to be able to be switched on and off at the same time or at different times.

Another advantageous refinement provides for the first LED chip to emit light at 400 to 430 nm and for the further LED chips to emit light at 450 to 480 nm.

Another advantageous refinement provides for the light curing device to be in the form of a hand-held device having a handle.

Another advantageous refinement provides for the light curing device to have a housing on which the converging lens is supported.

### BRIEF DESCRIPTION OF THE FIGURES

Further details, advantages and features emerge from the following description of a plurality of exemplary embodiments of the invention with reference to the drawing, in which:

FIG. 1 shows a diagrammatic view of a detail of an inventive semiconductor radiation source;

FIG. 2 shows a plan view of another detail of an embodiment of an inventive semiconductor radiation source;

FIG. 3 shows a section through a semiconductor radiation source;

FIG. 4 shows a section through another embodiment of a semiconductor radiation source;

FIG. 5 shows a plan view of the semiconductor radiation source in the embodiment shown in FIG. 4;

FIG. 6 shows a section through another embodiment of the inventive semiconductor radiation source;

FIG. 7 shows a plan view of the embodiment shown in FIG. 6;

FIG. 8 shows a plan view of part of an inventive radiation source; and

FIG. 9 shows a section through the embodiment shown in FIG. 8.

### DETAILED DESCRIPTION

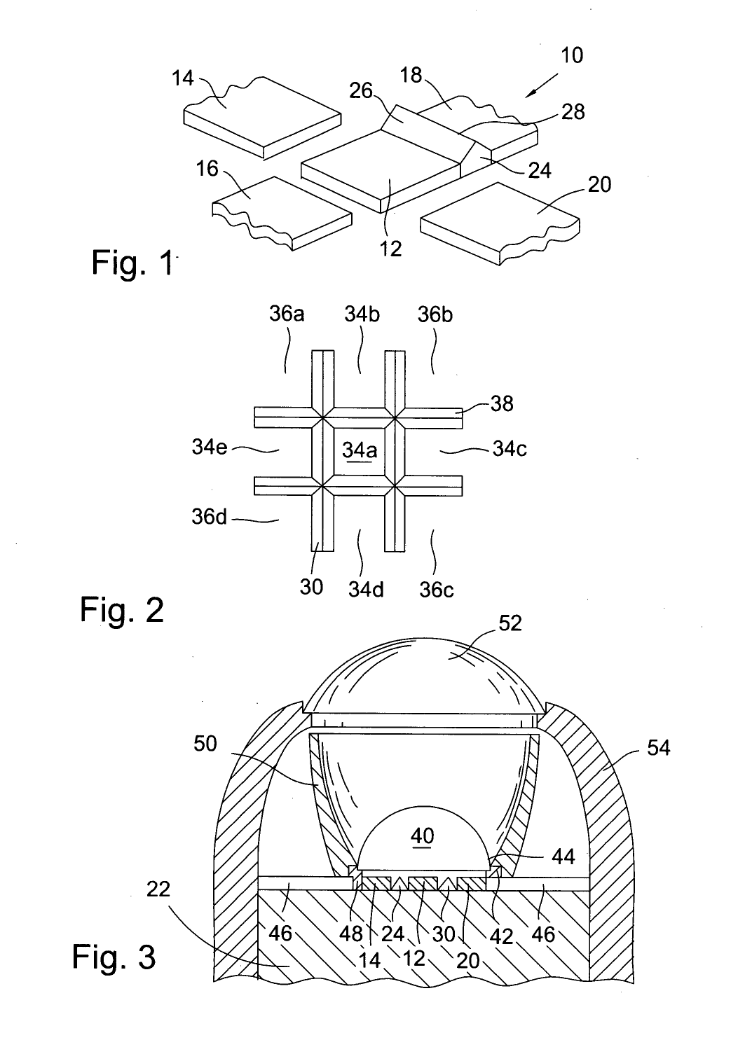

The semiconductor radiation source 10 which is partially illustrated in FIG. 1 has a plurality of LED chips (one centrally arranged chip 12 and four chips 14, 16, 18 and 20 which each extend along the side edges of said chip 12 in the exemplary embodiment illustrated). The chips are fitted to a base body 22 which is composed of metal and, at the same time, is used as a mounting base and as a heat sink. The base body is preferably at least partially composed of copper and/or is at least partially coated with gold or nickel/gold. Application is effected with a low thermal resistance between the chips and the base body 22, so that a high thermal power can also be dissipated.

A respective reflector element 24 which, in the side view, has an essentially roof-shaped structure is arranged between the central chip 12 and the adjacent chips 14 to 20. The reflector element 24 extends such that it adjoins the respective adjacent side areas of the LED chips 18 and 12 and is used to reflect the radiation from the LED chips which emerges via the side areas. The reflecting areas 26 and 28 extend approximately at an angle of 45° with respect to the surface of the base body 22, with the result that radiation which emerges obliquely from the chip 12 or 18 is reflected obliquely toward the front. As is known, reflection follows the principle that the angle of incidence is equal to the angle of reflection, with the result that the radiation in question regularly falls obliquely toward the front. A cover lens 40 which focuses the radiation is arranged in front of the LED chips, and a reflector 50 which continues to focus radiation, which is still emerging laterally, so that it can be passed to an inlet end of a light guide, which is arranged even further in front of the LED chips, is arranged in front of the cover lens.

It goes without saying that the angle of inclination of the reflecting areas 26 and 28 can be adapted to the requirements within wide ranges. More intense focusing of the main radiation results from an angle of inclination of, for example, 60° with respect to the surface of the base body 22, certain portions of the emerging radiation then being reflected back, that is to say being reflected to the opposite side beyond the optical axis of the cover lens, which is basically undesirable.

In the exemplary embodiments illustrated, the height of each reflector element may be considerably higher than the height of a chip. It goes without saying that this height can also be adapted to the requirements within wide ranges; for example, it may be in a range from the height of the chip to three times or even five times the height of the chip.

The reflector elements 24 also simultaneously act as spacers between the LED chips. They may also be provided on all four side edges of the chip 12, for example; a grating structure in accordance with the grating reflector 30 (as can be seen in FIG. 2) is also particularly favorable since this also makes it possible to simplify mounting of the chips. In this solution, the reflector elements 24 have been combined to form the grating reflector 30. Each web of the grating therefore has the corresponding roof-shaped cross section, that is to say essentially the cross section of an isosceles triangle when respectively viewed from the side, and the webs extend in the manner of a cross with respect to one another, as can be seen in FIG. 2. This leaves free areas, a respective LED chip—corresponding to the LED chips 12 to 20 from FIG. 1—being held in the free areas 34a, 34b, 34c, 34d and 34e in the refinement shown in FIG. 2, while the free areas 36a, 36b, 36c and 36d which are situated laterally beside the chips are also free of chips. It is preferred for the printed circuit board which is used to provide connecting areas for the LED chips to project into there. This preferred refinement, on the one hand, allows the printed circuit board to be brought very close to the chips, which is favorable for bonding, but, on the other hand, allows a compact chip arrangement to be ensured, which is favorable for optical reasons. It goes without saying that there is basically no need to provide oblique faces of the reflector element 24 in a manner adjoining the free areas 36a to 36d since no radiation is emitted there. In this respect, it is sufficient if the width of the grating structure 30 is halved there, that is to say oblique faces respectively extend toward the adjacent chip only on one side. For reasons of easier production and for reasons of better stability of the fingers of the grating reflector 30, a respective associated reflecting area may nevertheless be provided. For example, each LED chip may have an edge length of 1.5 mm, with the result that the width of each finger 38 of the grating structure may be, for example, 0.5 mm. However, a grating structure having finger widths of 0.5 mm can be handled in a considerably better manner than a grating structure having a finger width of 0.25 mm.

According to the invention, it is particularly favorable if the distance between the individual LED chips is less than ⅕, in particular approximately 1/10, of the diameter of each LED chip.

It goes without saying that the precise dimensions of the semiconductor radiation source 10 can be adapted to the requirements within wide ranges. It is particularly favorable if the total width of the chip arrangement of the inventive semiconductor radiation source 10, the distance from the outer edge of the chip 18 to the outer edge of the chip 16 or the distance from the outer edge of the chip 12 to the outer edge of the chip 20 is less than 8 mm, in particular less than 6 mm, and preferably approximately 5 mm, with the result that, on the one hand, it is possible to centrally arrange the LED chip arrangement on the base body but, on the other hand, favorable heat dissipation is nevertheless possible. Given these dimensions, the base body may have, for example, a width of approximately 1.5 cm and a length of approximately 2.5 cm and may be provided, in a manner known per se, with cooling ribs in regions which are lower down.

One modified refinement of an inventive semiconductor radiation source 10 can be seen in FIG. 3. Five LED chips are likewise arranged there in the manner of a cross, as is similarly provided in the embodiments shown in FIGS. 1 and 2. A grating structure 30 having reflector elements 24 whose height practically corresponds to the height of the LED chips extends between said chips. A cover lens 40 is provided such that it directly adjoins said reflector elements and said chips. The term “directly adjoins” is to be understood in this case as meaning that the cover lens 40 may rest on the top edges of the reflector elements 24 or may extend at a very short distance of, for example, 0.1 to 1 mm above the LED chips.

The cover lens 40 is supported using a spacer 42. The spacer 42 has an inner shoulder 44 which extends precisely to the periphery of the cover lens 40, laterally supports and engages around the latter.

The spacer 42 is mainly supported on a printed circuit board 46, the support additionally being effected on the base body 22 in the region of a stud 48. The printed circuit board 46 laterally extends toward the external LED chips 14 and 20, apart from the stud 48 which is illustrated in section in FIG. 3, but does not extend any further radially inward beside the chips 14 and 20, namely into the free areas 36a, 36b, 36c and 36d, with the result that parts of the printed circuit board respectively extend between the external LED chips, that is to say, for example, between the chip 14 and the chip 16. Connecting areas which cannot be seen in FIG. 3 are formed precisely there, that is to say in the region of the free areas 36a to 36d.

Contact-connection is preferably effected in such a manner that the base body 22 is used as a ground body, while conductor tracks which extend on the top of the printed circuit board 46 and ensure connection are routed to the chips 12 to 20.

A reflector 50 which, in a manner known per se, has a parabolic surface extends above the spacer 46. It adjoins the front side of the cover lens 40. As a result of this interposition, it is additionally thermally separated from the hot LED chips 12 to 20 and from the base body 22 which is likewise very warm, with the result that said reflector does not tend to become opaque even if inexpensive plastic material is used.

A converging lens 52 which is mounted on an inner shoulder in the housing 54 extends at a certain distance from the reflector element such that it overlaps the latter. The housing 54, in turn, holds the base body 22, so that, in this respect, there is a fixed spatial assignment between the reflector 50 and the converging lens 52.

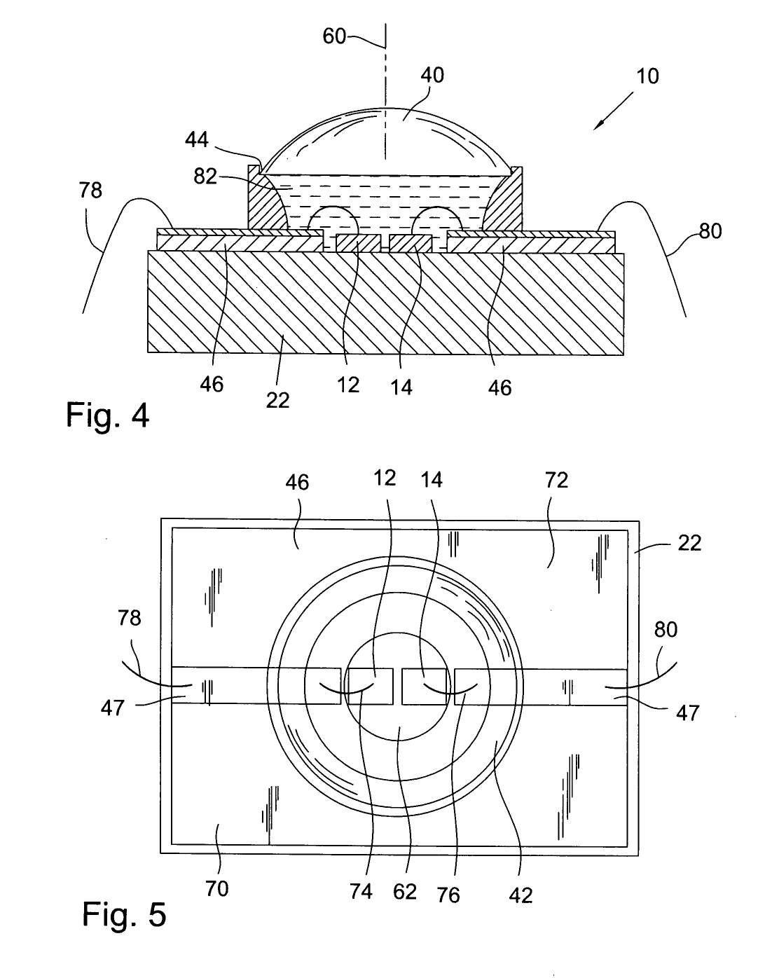

One modified refinement of the inventive radiation source can be seen in FIG. 4. In this solution, a plurality of LED chips 12, 14 are centrally arranged in a compact manner on the base body 22. As also in the case of the embodiments shown in FIGS. 1 to 3, the LED chips are arranged such that they are closely adjacent, in which case one reflector element, at most, extends between them and, in the exemplary embodiment illustrated, no reflector element is provided.

According to the invention, it is particularly favorable if a printed circuit board does not extend between the optical axis 60 and the chips but rather a close arrangement is provided in this respect, while a printed circuit board can laterally extend into the region of the LED chips. In the embodiment shown in FIGS. 4 and 5, the printed circuit board 46 is clearly provided outside the chip arrangement and surrounds the latter in the form of an annulus, as can be seen in FIG. 5. It also covers virtually the entire surface of the base body 22, with the result that there is good heat insulation toward the front. Apart from this, there is only one central chip region 62 which holds the chips 12 and 14. Even if this circular region is illustrated on a very large scale in FIG. 5, it goes without saying that, instead of this, it may also be favorable to bring the printed circuit board closer to the chips.

As can be seen in FIG. 5, the conductor tracks 47 extend from connecting areas 70, 72 for bonding wires 74, 76 to the outside, that is to say to the outer periphery of the base body 22, and are connected there via connecting wires 78, 80.

The spacer 42 for the cover lens 40 extends in the form of an annulus (cf. FIG. 5), the cover lens 40, in turn, being held on an inner shoulder 44. A space 82 which is laterally bounded by the annular spacer 42 is formed between the planar rear side of the cover lens 40 and the chip region such that it is closed. This space is preferably provided with a transparent substance such as silicone gel or a potting compound which may, if appropriate, have phosphorus particles.

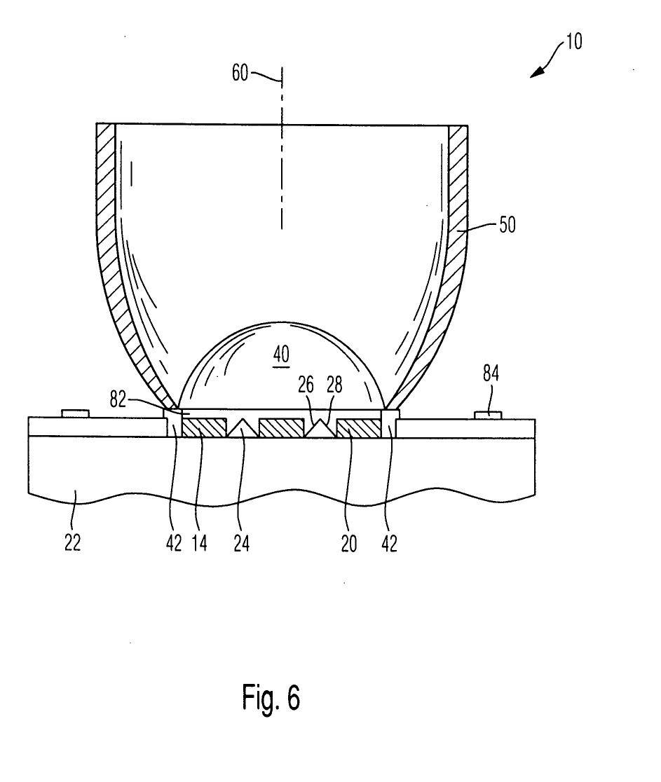

One refinement (which has been modified further) of the inventive radiation source 10 can be seen in FIG. 6. The same reference symbols refer to the same parts in this case and in the further figures. This refinement is distinguished by a design which is likewise very compact and in which the LED chips are arranged in the form of a cross or star, nothing which is extraneous to the chip—apart from a very compact reflector element 24, if appropriate—extending between the external LED chips 14 and 20 and the optical axis 60. The reflector elements 24 are, in turn, of roof-shaped design, with the result that they provide reflecting areas 26 and 28 and cast the laterally emerging light toward the front.

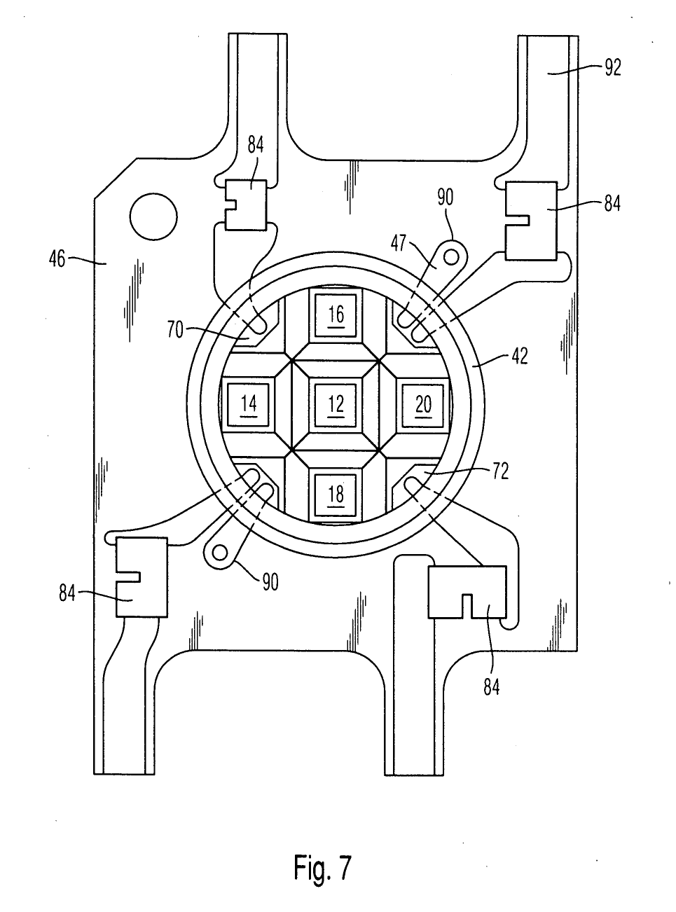

It can be seen in FIG. 7, but also in FIG. 6, that a respective series resistor 84 which can be used for adjustment purposes when the LED chips are also connected in parallel, in particular, is connected to the conductor tracks 47. This can be seen better in FIG. 7 which shows a total of four series resistors 84 which have each been adjusted using laser trimming and are assigned to the four external LED chips 14 to 12. This solution provides for the central LED chip 12 to be operated independently at another wavelength, while the external LED chips 14 to 20 are each connected in parallel and therefore have series resistors in their conductor tracks 47.

In the exemplary embodiment illustrated, the printed circuit board 46 is provided with contact vias 90 which allow the connecting lugs 92 to be contact-connected from above and below.

As can be seen in FIG. 7, connecting areas, for example the connecting areas 70 and 72, extend from the outside beside the external LED chips 14 to 20, while the chip region remains free of conductor tracks toward the inside, that is to say toward the optical axis.

Despite the compact arrangement, this solution allows the conductor tracks to be terminated within the spacer 42, so that bonding wires can run to the chips in a protected manner but a joint cover lens 40 (which cannot be seen in FIG. 7) can nevertheless extend above all of the chips 12 to 20.

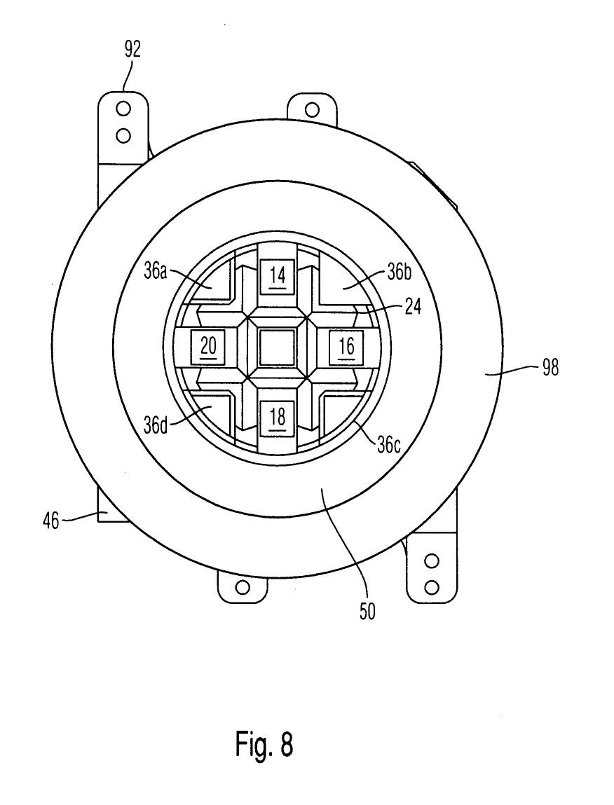

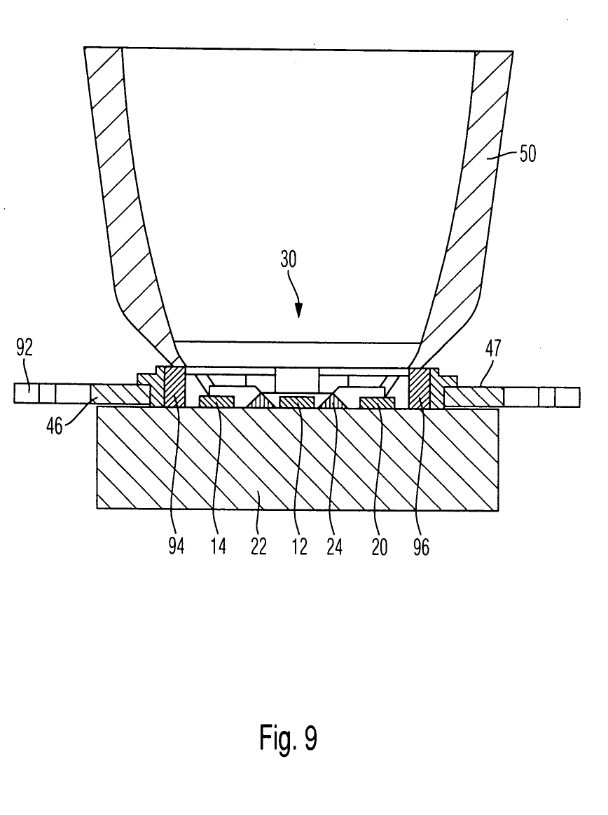

Another embodiment can be seen in FIGS. 8 and 9. Identical or similar reference symbols refer to identical or similar parts there and in the further figures. In this solution, five LED chips 12 to 20 are again essentially arranged in the form of a cross, with the result that the chips 14 to 20 surround a central chip 12. The chips are each surrounded by reflector elements 24 which extend between said chips and beside the latter and form part of a spacer which supports a reflector 50 in front of the LED chips.

In the plane of the drawing beneath the reflector 50 and as can be seen better in FIG. 9, provision is made of radiation absorbers 94 and 96 which extend between the external LED chips 14 and 20, on the one hand, and the printed circuit board 46. This solution is particularly favorable when high-energy radiation needs to be intercepted without impairing the printed circuit board. The radiation absorbers 94 and 96 may be applied to the base body 22 in the form of solid bodies, for example using an extremely thin adhesive layer, also similar to the chips themselves, so that good heat dissipation is ensured.

The radiation absorbers 94 and 96, of which two corresponding radiation absorbers are of course likewise provided for the further LED chips 16 and 18, may be composed of any desired suitable materials. Plastic bodies, aluminum bodies but also preferably ceramic bodies which may also be dyed dark in order to ensure even better radiation absorption are suitable, for example.

In the exemplary embodiment illustrated in FIG. 8, the printed circuit board 46 is also covered by a protective ring 98 which is likewise used for better protection, in particular of the calibration resistors, since calibration can be impaired as a result of excessive heating of the calibration resistors.

It goes without saying that the protective ring 98 is dimensioned in such a manner that the connecting tracks 92 remain free, the protective ring preferably being configured to be electrically insulating at least on its underside.

It can be seen in FIG. 9 that the LED chips 14, 12 and 20 are each also arranged at a distance from the reflector element. This also contributes to preventing the intensive emission of heat by the LED chips from becoming intensive application of heat to the grating reflector 30 which may be composed of plastic with mirrored surfaces.

Even if the illustration shown in FIG. 9 does not illustrate a lens corresponding to the cover lens 40, it goes without saying that said lens may be provided there in any desired suitable manner.

While a preferred form of this invention has been described above and shown in the accompanying drawings, it should be understood that applicant does not intend to be limited to the particular details described above and illustrated in the accompanying drawings, but intends to be limited only to the scope of the invention as defined by the following claims. In this regard, the term “means for” as used in the claims is intended to include not only the designs illustrated in the drawings of this application and the equivalent designs discussed in the text, but it is also intended to cover other equivalents now known to those skilled in the art, or those equivalents which may become known to those skilled in the art in the future.

What is claimed is:

1. A semiconductor radiation source for curing light-polymerizable materials comprising:
a base body (22);
at least two centrally arranged LED chips directly mounted to the base body using a thermally conductive connection;
at least one printed circuit board (46) mounted on the base body and which extends from the centrally arranged LED chips to the outside, in particular to the peripheral region of the base body (22).

2. The radiation source as claimed in claim 1, wherein the printed circuit board (46) projects into free areas which extend laterally beside the chips.

3. The radiation source as claimed in claim 1, wherein the printed circuit board (46) runs beside the chips but not between the chips and the optical axis (60) of the radiation source.

4. The radiation source as claimed in claim 1, wherein a first LED chip (12) is arranged on an optical axis (60) and a plurality of several LED chips (14, 16, 18, 20) are radially arranged outside the first LED chip (12), in particular in such a manner that they are symmetrical with respect to one another and surround the LED chip (12) in the manner of a cross or star.

5. The radiation source as claimed in claim 1, wherein four further LED chips (14, 16, 18, 20) surround the first LED chip (12).

6. The radiation source as claimed in claim 1, wherein the LED chips are arranged in the central region of the base body (22) such that they are adjacent to one another, that is to say without the printed circuit board (46) between them.

7. The radiation source as claimed in claim 1, wherein the printed circuit board (46) surrounds the LED chips.

8. The radiation source as claimed in claim 1, wherein the LED chips and the printed circuit board (46) essentially have the same height.

9. The radiation source as claimed in claim 1, wherein connecting areas (70, 72) of conductor tracks (47) of the printed circuit board (46) are connected to the LED chips via bonding connections, in particular.

10. The radiation source as claimed in claim 1, wherein the LED chips are directly mounted on the base body (22), if appropriate using a thermally conductive adhesive, and the printed circuit board (46) is, in particular, adhesively bonded to the base body (22).

11. The radiation source as claimed in claim 1, wherein the printed circuit board (46) has an epoxy resin base, has at least one conductor track (47) at least on one side, is coated with copper, in particular, and is connected by through-plating.

12. The radiation source as claimed in claim 1, wherein a reflector element (24) which is arranged at least between two mutually adjacent LED chips.

13. The radiation source as claimed in claim 12, wherein a reflector element (24) which extends between two LED chips has two reflecting areas (26, 28) which run essentially obliquely, each reflecting area reflecting radiation emanating from the adjacent LED chip.

14. The radiation source as claimed in claim 13, wherein the reflecting areas (26, 28), when viewed in the direction of the optical axis (60), essentially extend in a manner corresponding to the height of the printed circuit board (46) or project beyond the printed circuit board (46).

15. The radiation source as claimed in claim 12, wherein a plurality of reflector elements (24) are connected to one another so as to form a grating reflector (30).

16. The radiation source as claimed in claim 15, wherein the LED chips are held in the grating reflector (30), and wherein the grating reflector is supported on the base body (22) and/or the printed circuit board (46) and/or the LED chips.

17. The radiation source as claimed in claim 2, wherein reflector elements (24) extend between the lateral free areas (34, 36) and the LED chips and support the LED chips.

18. The radiation source as claimed in claim 1, wherein radiation absorbers are connected, in particular, to the base body (22) using thermally conductive connections extend between a centrally located LED chip (12) and external LED chips (14, 16, 18, 20), in particular the external LED chips (14, 16, 18, 20), and the printed circuit board (46).

19. The radiation source as claimed in claim 18, wherein the radiation absorbers are simultaneously of heat-insulating design and are composed of ceramic, in particular.

20. The radiation source as claimed in claim 18 wherein the radiation absorbers extend at least over the width of the LED chips (14, 16, 18, 20) and, in particular, have a greater height than the LED chips (14, 16, 18, 20), preferably approximately 1.5 to 5 times the height, and particularly preferably approximately twice the height, of the LED chips (14, 16, 18, 20).

21. The radiation source as claimed in claim 1, wherein a cover lens (40) is arranged in the beam path downstream of the LED chips and a spacer (42) for said lens is of essentially tubular or annular design, and wherein the spacer (42) is at least partially supported on the printed circuit board (46) and/or the base body (22).

22. The radiation source as claimed in claim 21, wherein at least one conductor track of the printed circuit board (46) runs through under a spacer (42) and, in particular, runs from outside the spacer (42) to inside the spacer.

23. The radiation source as claimed in claim 20 wherein a closed space (82) which has a transparent or translucent, liquid or gelatinous substance, in particular silicone gel or a potting compound, extends between the LED chips, the spacer (42) and the cover lens (40).

24. The radiation source as claimed in claim 23, wherein the substance has phosphorus particles.

25. The radiation source as claimed in claim 21, wherein a converging lens (52) whose diameter is, in particular, larger than the diameter of a cover lens (40) is arranged in the beam path downstream of the cover lens (40).

26. The radiation source as claimed in claim 21, wherein a reflector (50) is arranged at a distance from the LED chips in front of the latter, that is to say downstream of the latter in the beam path, and/or is also arranged, in particular, downstream of a cover lens (40) in the beam path.

27. The radiation source as claimed in claim 26, wherein a light guide is arranged in the beam path downstream of the reflector (50).

28. The radiation source as claimed in claim 1, wherein series resistors (84) which can be adjusted, in particular, and are freely accessible for adjustment are arranged on the printed circuit board (46) outside the spacer (42).

29. The radiation source as claimed in claim 1, wherein the first LED chip (12) and the further LED chips (14, 16, 18, 20) emit light at different wavelengths, in particular at 400 to 430 nm, on the one hand, and at 450 to 480 nm, on the other hand.

30. The radiation source as claimed in claim 1, wherein the first chip (12) and the further chips (14, 16, 18, 20) can be switched on and off at the same time or at different times.

31. The radiation source as claimed in claim 1, wherein the first LED chip (12) emits light at 400 to 430 nm and the further LED chips (14, 16, 18, 20) emit light at 450 to 480 nm.

32. The light curing device as claimed in claim 1 wherein the light curing device has a housing (54) on which the converging lens (52) is supported.
